(19) United States
(12) Patent Application Publication
(10) Pub. No.: US 2011/0050211 A1
(43) Pub. Date: Mar. 3, 2011

(54) TRAPEZOIDAL READER FOR ULTRA HIGH DENSITY MAGNETIC RECORDING

(75) Inventors: Kaizhong Gao, Eden Prairie, MN (US); Jiaoming Qiu, St. Paul, MN (US); Lei Wang, Maple Grove, MN (US); Yonghua Chen, Edina, MN (US)

(73) Assignee: Seagate Technology LLC, Scotts Valley, CA (US)

(21) Appl. No.: 12/547,832

(22) Filed: Aug. 26, 2009

(51) Int. Cl. G01R 33/09; G11B 5/127

(52) U.S. Cl. 324/207.21; 360/324; G9B/5.04

(57) ABSTRACT

A magnetic sensor comprises a sensor stack and magnetic bias elements positioned adjacent each side of the sensor stack. The sensor stack and bias elements have substantially trapezoidal shapes.

### BACKGROUND

In a magnetic data storage and retrieval system, a magnetic recording head typically includes a reader portion having a magnetoresistive (MR) sensor for retrieving magnetically encoded information stored on a magnetic disc. Magnetic flux from the surface of the disc causes rotation of the magnetization vector of a sensing layer or layers of the MR sensor, which in turn causes a change in electrical resistivity of the MR sensor. The sensing layers are often called “free” layers, since the magnetization vectors of the sensing layers are free to rotate in response to external magnetic flux. The change in resistivity of the MR sensor can be detected by passing a current through the MR sensor and measuring a voltage across the MR sensor. Depending on the geometry of the device, the sense current may be passed in the plane (CIP) of the layers of the device or perpendicular to the plane (CPP) of the layers of the device. External circuitry then converts the voltage information into an appropriate format and manipulates that information as necessary to recover the information encoded on the disc.

The essential structure in contemporary read heads is a thin film multilayer containing ferromagnetic material that exhibits some type of magnetoresistance. Examples of magnetoresistive phenomena include anisotropic magnetoresistance (AMR), giant magnetoresistance (GMR), and tunneling magnetoresistance (TMR).

For all types of MR sensors, magnetization rotation occurs in response to magnetic flux from the disc. As the recording density of magnetic discs continues to increase, the width of the tracks on the disc must decrease, which necessitates smaller and smaller MR sensors as well. As MR sensors become smaller in size, particularly for sensors with dimensions less than about 0.1 micrometers (μm), the sensors have the potential to exhibit an undesirable magnetic response to applied fields from the magnetic disc. MR sensors must be designed in such a manner that even small sensors are free from magnetic noise, sufficiently stable, and provide a signal with adequate amplitude for accurate recovery of the data written on the disc.

### SUMMARY

A magnetic sensor comprises a sensor stack and magnetic bias elements positioned adjacent each side of the sensor stack. The sensor stack and bias elements have substantially trapezoidal shapes.

A magnetoresistive read head comprises a first bias element and a second bias element with a magnomagnetoresistive stack positioned between the bias elements. The magnetoresistive stack and bias elements have substantially trapezoidal shapes.

A magnetoresistive sensor comprises a sensor stack positioned between two magnetic bias elements. The sensor stack and bias elements have shapes that stabilize a “C” state of the sensor stack when under the influence of a bias magnetic field.

### BRIEF DESCRIPTION OF THE DRAWINGS

FIG. 1 is a schematic diagram of a prior art reader with rectangular bias magnets and a rectangular reader stack.

FIG. 2A is a schematic diagram showing micromagnetic magnetization patterns in a rectangular freelayer of a prior art reader design.

FIG. 2B is a schematic diagram showing a “C” type micromagnetic magnetization pattern.

FIG. 2C is a schematic diagram showing an “S” type micromagnetic magnetization pattern.

FIG. 3 is a schematic diagram showing a “C” type micromagnetization pattern in a trapezoidal freelayer and bias magnets of the current reader.

FIG. 4 is a schematic diagram illustrating the response of a MR sensor to the effect of a bit field source versus the distance of the sensor from the field source.

FIG. 5 is a micromagnetic simulation of the response of a prior art MR sensor and an inventive MR sensor to a bit field source versus the distance of the sensors from the field source.

FIG. 6A is a schematic diagram showing an alternative embodiment of a current reader.

FIG. 6B is a schematic diagram showing an alternative embodiment of the current reader.

### DETAILED DESCRIPTION

A principal concern in the performance of magnetoresistive read sensors is fluctuation of magnetization in the read sensor, which directly impacts the magnetic noise of the read sensor. There are three major components of noise that decrease the SN ratio of a reader: Shot noise, Johnson noise, and thermal magnetic noise. All are related to the RA product and become increasingly disruptive to the SN ratio as the reader area decreases in size. Shot noise results from random fluctuations in electron density in an electric current and is proportional to the current I, the band width Δf, and the resistance R. The noise power, Pₛ, in a resistor due to Shot noise in a resistor is: Pₛ=f(IΔf RA/A).

Johnson noise results from thermal fluctuations in electron density in a conductor regardless of whether a current is flowing and is proportional to the temperature T, band width Δf, and the resistance R. The noise power Pⱼ in a resistor due to Johnson noise is: Pⱼ=f(TΔf RA/A).

Thermal magnetic noise results from thermally induced magnetic fluctuations in the sensing layers of the reader and is proportional to the temperature T; band width Δf; the reader bias field to the free ferromagnetic layer H_{bias}; the magnetic moment of the freelayer M_{sf}; and the volume of the freelayer, V_{free}. The noise power, P_{mag}, in a resistor due to thermal magnetic noise is: P_{mag}=f(TΔf/H²_{bias}M_{sf}V_{free}).

The RA product of a CPP or TMR sensor is an intrinsic value depending on the material. As the sensor area decreases, the resistance as well as the Shot noise and Johnson noise levels increase. The thermal magnetic noise level varies inversely as the free layer volume of the sensor and also increases accordingly as the sensor area decreases. The resistance increase problem can be overcome with a shunt resistor, but the reader loses signal amplitude. From a reader performance standpoint, it is advantageous to maximize the reader area while maintaining a small reader footprint at the ABS.

RTN noise is an additional noise component to the reader outpoint signal. RTN noise originates from the existence of two remanent magnetization patterns in the sensor that are energetically close enough and have a low energy barrier such that thermal activation can cause oscillation between the two states. Each magnetization pattern (termed “C” state and “S” state) has a different resistance that adds noise to the sensor output signal. Thus there is an additional challenge to stabilize the “C” state or “S” state in addition to maximizing reader area while maintaining a small reader footprint at the ABS.

The reader disclosed herein reduces the above mentioned noise levels for a given recording geometry as well as permitting a higher playback amplitude.

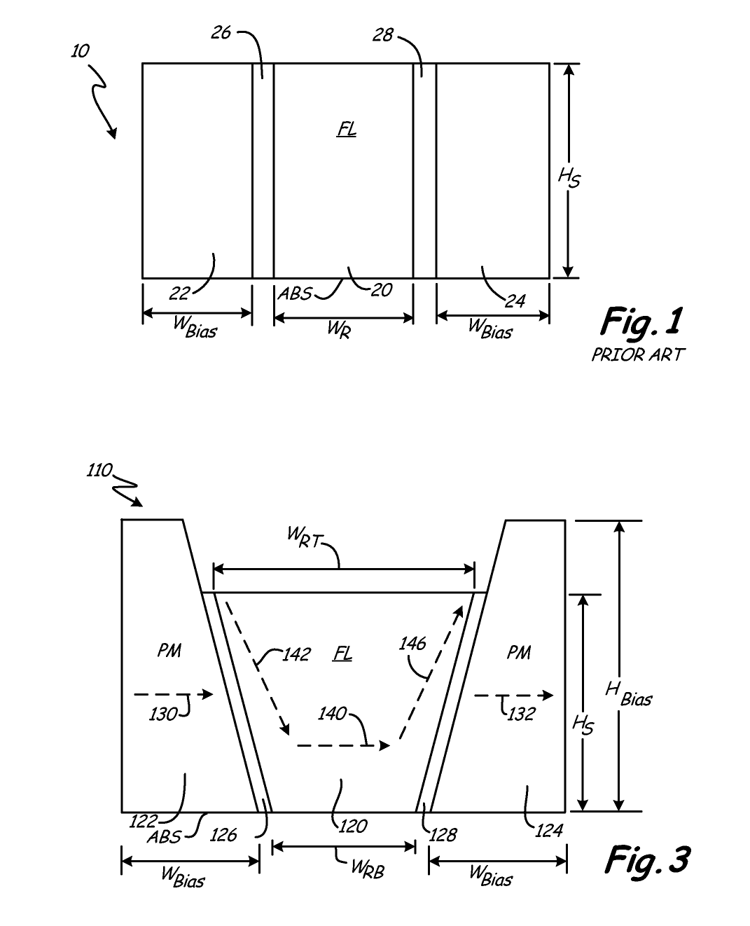

FIG. 1 shows prior art reader 10, which includes rectangular reader stack 20, rectangular bias elements 22 and 24, and nonmagnetic spacers 26 and 28. Reader stack 20 includes magnetic and nonmagnetic layers, including at least one free layer. Stack 20 has a reader width W_{R} and a stripe height H_{S}. Each of bias elements 22 and 24 has a width W_{Bias}. Widths W_{R} and W_{Bias} are uniform from air bearing surface ABS to the top of reader 10. Spacers 26 and 28 are nonmagnetic, and may be, for example, metal or ceramic.

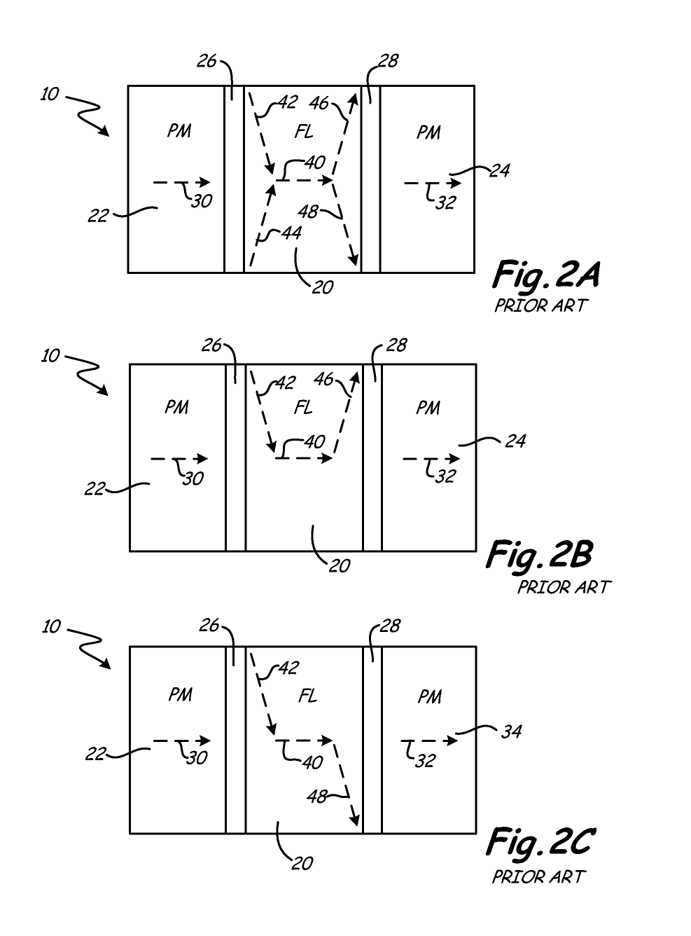

FIG. 2A is a schematic diagram showing a top view of micromagnetic magnetization patterns in free layer FL of reader stack 20 in prior art sensor 10. Magnetization in bias elements 22 and 24 is indicated by arrows 30 and 32, respectively. Arrow 40 depicts primary magnetization in free layer FL of sensor stack 20 resulting from bias magnets 22 and 24. The micromagnetic magnetization patterns in free layer FL of sensor stack 20 are preferably parallel to the borders close to bias magnets 22 and 24 due to demagnetization effects as shown by arrows 42, 44, 46 and 48. The magnetization in free layer FL exists in two states that are energetically close and that change from one to another as a result of thermal activation. A “C” state is shown in FIG. 2B comprising magnetization vectors 40, 42 and 46. Another “C” state can be represented by vectors 44, 40 and 48. An alternate state designated an “S state”, is shown in FIG. 2C comprising magnetization vectors 42, 40 and 48. Another “S” state can be represented by vectors 44, 40 and 46. Changing magnetization resulting from thermally activated fluctuations between the “C” and “S” states results in RTN noise.

The inventive reader disclosed herein stabilizes the “C” state at the expense of the “S” state and minimizes RTN noise. FIG. 3 shows reader 110, which includes sensor stack 120, permanent magnet bias elements 122 and 124, and spacers 126 and 128. Sensor stack 120 and bias elements 122 and 124 have trapezoidal shapes, that, as shown by micromagnetization vectors 142, 140 and 146 in free layer FL of sensor stack 120, stabilize the “C” state when under the influence of bias magnetization vectors 130 and 132. The dimensions of trapezoidal sensor stack 120 are reader base width W_{RB}, reader top width W_{RT}, and stripe height H_{S}. The dimensions of this aspect of the invention are base width W_{RB} of about 20 nm, top width W_{RT} of about 40 nm, and height H_{S} of about 30 nm. In another aspect, reader top width W_{RT} is at least 10 percent wider than reader base width W_{RB}.

The trapezoidal geometry shown in FIG. 3 offers an increased reader area and resulting RA product at no expense to the reader footprint at the ABS. In this aspect of the present invention, the increased width W_{Bias} of trapezoidal bias elements 122 and 124 at the ABS increases the bias field in that vicinity. In another aspect, by extending the height H_{Bias} of the bias magnets beyond reader stripe height H_{S}, the “C” micromagnetic magnetization pattern is enhanced and RTN noise is minimized.

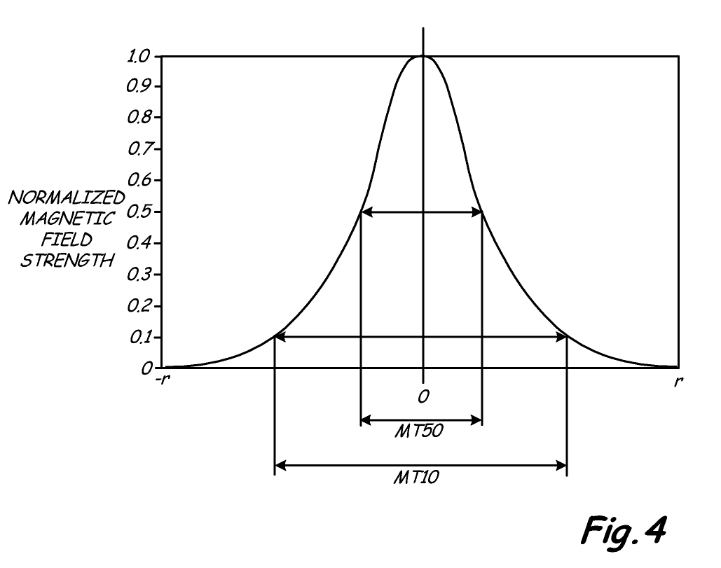

FIG. 4 is a plot showing the response of MR sensor 110 due to the field from a very narrow track (called micro-track) on a recording medium as a function of the distance r of sensor 110 from the bit. A normalized peak magnetic field strength detected by the sensor from the narrow track is plotted on the Y axis and the relative separation r of the sensor from the bit is plotted on the X axis. The signal is greatest when the sensor is directly on the bit at X=0. As the separation between MR sensor 110 and the bit increases, the signal strength decreases rapidly, that is, it decays. The curve is plotted to indicate a 1/r² relationship between signal strength and separation r. The distance between two positions on the media, at which the signal strength decreases 50% from its maximum, is known as MT50. The distance between two positions on the media, at which the signal decreases to 10% of its maximum, is known in as MT10. The ratio MT10/MT50 is an indication of the ability of sensor 110 to detect magnetic fields from adjacent tracks that distort the sensing signal.

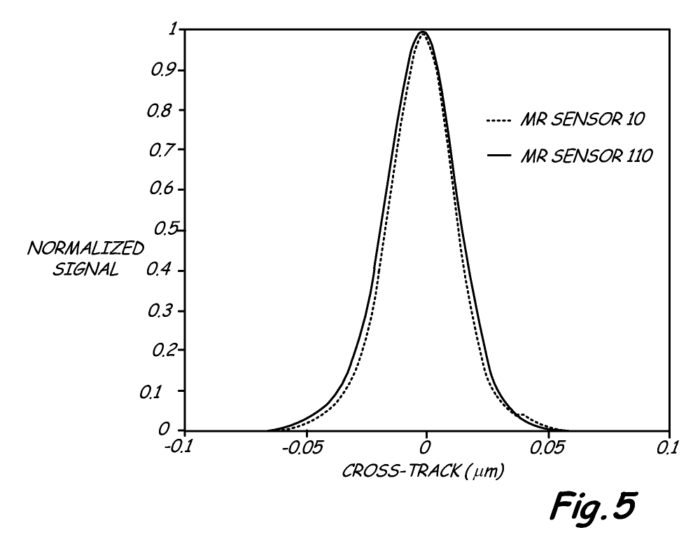

Since trapezoidal sensor stack 120 is about 10% wider than rectangular sensor stack 20, it is helpful to know how the cross track signal profile changes between the two sensors. Micromagnetic modeling of cross track signal strength from the same micro-track on the two sensor geometries gave the results shown in FIG. 5. The FIG. shows signal strength as a function of distance from the micro-track center on a recording medium for sensor 10 and sensor 110. The two curves almost superimpose, indicating that increasing the top width (and area) of trapezoidal sensor 120 has not affected sensor cross-track performance. MT10/MT50 of both sensors 10 and 110 are about the same.

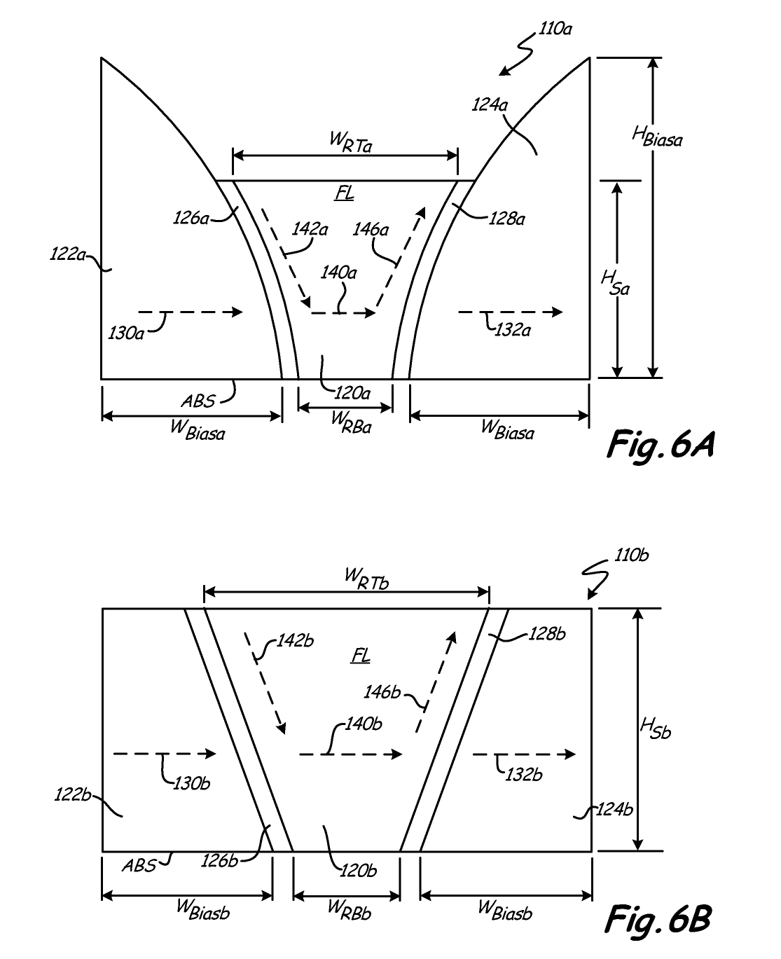

FIGS. 6A and 6B are schematic illustrations of two alternative aspects of the present reader. FIG. 6A shows reader 110a, which includes sensor stack 120a, permanent bias magnet elements 122a and 124a and spacers 126a and 128a. Sensor stack 120a and bias elements 122a and 124a have shapes that, as shown by micromagnetization vectors 142a, 140a, and 146a in free layer FL of sensor stack 120a, stabilize the “C” state when under the influence of bias magnetization vectors 130a and 132a. In one embodiment the sensor stack and permanent bias magnets are curved designs. The dimensions of sensor stack 120a are reader base width W_{RBa}, reader top width W_{RTa} and stripe height H_{Sa}. The dimensions of this aspect of the invention are base width W_{RBa} of about 20 nm, top width W_{RTa} of about 40 nm, and height H_{Sa} of about 30 nm. In another aspect, reader top width W_{RTa} is at least 10 percent wider than reader base width W_{RBa}.

The geometry shown in FIG. 6A offers an increased reader area and resulting RA product at no expense to the reader footprint at the ABS. In this aspect of the present invention, the increased width, W_{Biasa} of bias elements 122a and 124a at the ABS increases the bias field in that vicinity. In another aspect, by extending the height H_{Biasa} of the bias magnets beyond the reader stripe height H_{Sa}, a “C” micromagnetization pattern is enhanced and RTN noise is minimized.

FIG. 6B shows reader 110b, which includes sensor stack 120b, permanent magnet bias elements 122b and 124b and spacers 126b and 128b. Sensor stack 120b and bias elements 122b and 124b have shapes that, as shown by micromagnetization vectors 142b, 140b and 146b in freelayer FL of sensor stack 120b, stabilize the “C” state when under the influence of bias magnetization vectors 130b and 132b. The dimensions of sensor stack 120b are reader base width W_{RBb}, reader top width W_{RTh} and stripe height H_{Sb}. The dimensions of this aspect of the invention are base width W_{RBb} of about 20 nm, top width W_{RTh} of about 40 nm, and height H_{Sb} of about 30 nm. In another aspect, reader top width W_{RTh} is at least 10 percent wider than reader base width W_{RBb}. The geometry shown in FIG. 6B offers an increased reader area and resulting RA product at no expense to the reader footprint at the ABS. In this aspect of the present invention, the increased width W_{Biasb} of bias elements 122b and 124b at the ABS increases the bias field in that vicinity.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A magnetic sensor comprising:
a sensor stack;
a first bias element positioned adjacent a first side of the sensor stack; and
a second bias element, adjacent a second side of the sensor stack;
wherein the sensor stack and bias elements have substantially trapezoidal shapes in top view.

2. The magnetic sensor of claim 1 wherein the sensor stack is a magnetoresistive stack.

3. The magnetic sensor of claim 2 wherein the magnetoresistive stack is a current perpendicular to plane (CPP) stack.

4. The magnetic sensor of claim 1 further comprising a first spacer layer between the first bias element and the sensor stack and a second spacer layer between the second bias element and the sensor stack.

5. The magnetic sensor of claim 1 wherein the first and second bias elements are permanent magnetic bias elements.

6. The magnetic sensor of claim 1 wherein the sensor stack has a first width and a second width different from the first width and wherein the first width is less than the second width.

7. The magnetic sensor of claim 6 wherein the first width is proximal an air bearing surface and the second width is distal the air bearing surface.

8. The magnetic sensor of claim 5 wherein a distance from an air bearing surface to a top of the bias elements is greater than a distance from the air bearing surface to a top of the sensor stack.

9. The magnetic sensor of claim 6 wherein the second width is at least ten percent wider than the first width.

10. The magnetic sensor of claim 5 wherein a distance from an air bearing surface to a top of the bias elements is about equal to a distance from the air bearing surface to a top of the sensor stack.

11. The magnetic sensor of claim 7 wherein the first width is about 20 nm, the second width is about 40 nm and a stack height is about 30 nm.

12. A magnetoresistive read head comprising:
a first bias element;
a second bias element; and
a magnetoresistive stack positioned between the first bias element and the second bias element;
wherein the magnetoresistive stack and bias elements have substantially trapezoidal shapes in top view.

13. The magnetoresistive stack of claim 12 wherein the first and second bias elements are permanent magnetic bias elements.

14. The magnetoresistive read head of claim 12 wherein the sensor stack has a first width and a second width different from the first width and wherein the first width is less than the second width.

15. The magnetoresistive read head of claim 14 wherein the first width is proximal an air bearing surface and the second width is distal the air bearing surface.

16. The magnetoresistive read head of claim 14 wherein a distance from the air bearing surface to the top of the bias elements is greater than the distance from the air bearing surface to the top of the sensor stack.

17. The magnetoresistive read head of claim 14 wherein the second width is at least ten percent wider than the first width.

18. The magnetoresistive read head of claim 14 wherein the first width is about 20 nm and the second width is about 40 nm.

19. A magnetoresistive sensor comprising:
a sensor stack;
a first bias element positioned adjacent a first side of the sensor stack; and
a second bias element adjacent a second side of the sensor stack;
wherein the sensor stack and bias elements have a shape that stabilizes a “C” state of the sensor stack when under an influence of a bias magnetization vector.

20. The magnetoresistive sensor of claim 19 wherein the sensor stack has a curved trapezoidal shape and the bias elements have a curved triangular shape.
